(19) United States
(12) Patent Application Publication
(10) Pub. No.: US 2024/0290587 A1
(43) Pub. Date: Aug. 29, 2024

(54) APPARATUS AND METHOD FOR TREATING SUBSTRATE

(71) Applicant: SEMES CO., LTD., Cheonan-si, Chungcheongnam-do (KR)

(72) Inventors: Dong Hun KIM, Gunpo-si, Gyeonggi-do (KR); Hyun Min LIM, Osan-si, Gyeonggi-do (KR); Hwa Il YUN, Hwaseong-si, Gyeonggi-do (KR)

(21) Appl. No.: 18/394,198

(22) Filed: Dec. 22, 2023

(30) Foreign Application Priority Data
Feb. 27, 2023 (KR) 10-2023-0025858

(51) Int. Cl. H01J 37/32

(52) U.S. Cl. CPC H01J 37/3288; H01J 37/32183; H01J 37/3244; H01J 37/32568; H01J 37/32577; H01J 2237/3341

(57) ABSTRACT

A substrate treatment apparatus includes a processing chamber including an upper chamber and a lower chamber having a treatment space for treating a substrate, a substrate support unit provided in the treatment space, the substrate support unit fixing the substrate, a gas supply unit supplying a process gas to the inside of the upper chamber and the treatment space, a plasma generation unit including an upper electrode provided in the upper chamber and a high-frequency power source connected to the upper electrode, the high-frequency power source supplying high-frequency power through an impedance matcher, and a filter unit connected to the upper electrode, the filter unit removing charges accumulated on one surface of the upper electrode.

### CROSS-REFERENCE TO RELATED APPLICATION(S)

This application claims benefit of priority to Korean Patent Application No. 10-2023-0025858 filed on Feb. 27, 2023 in the Korean Intellectual Property Office, the disclosure of which is incorporated herein by reference in its entirety.

### TECHNICAL FIELD

The present disclosure relates to a substrate treatment apparatus and substrate treatment method for reducing electrostatic charging of a power electrode.

In general, in order to manufacture a semiconductor device, a substrate may be subjected to various processes such as etching, ashing, ion implantation, thin film deposition, and cleaning to form a desired pattern on the substrate. Here, the etching process may be a process of removing a selected heating region of a film formed on the substrate, and wet etching and dry etching may be used.

In a dry process, chemical treatment using radicals and physical treatment using ions may be performed. In order to perform the chemical treatment and the physical treatment independently of each other, there has been proposed a double chamber structure vertically divided into an ion blocker, allowing electrically neutral substances such as radicals and gases to pass therethrough, but not allowing ions to be pass therethrough, and a showerhead.

Electrostatic charging may occur in an upper power electrode as charges are accumulated due to coolant circulation. As a method for removing the accumulated charges, a technique capable of removing charges by directly generating ions has been disclosed. However, there is a risk of arcing as an output unit of an ionizer is exposed on a propagation path, and the movement of the generated ions may affect the electric field distribution for plasma generation.

In addition, another disclosed related art technique may indirectly change an ambient electric field to remove the accumulated charges, which has a limitation of requiring an electrode and only being used with a high-frequency electric field turned off, which may cause arcing or affect the electric field distribution.

Patent Document: U.S. Pat. No. 9,704,714 B2.

### SUMMARY

Aspects of the present disclosure provide a substrate treatment apparatus and substrate treatment method for reducing electrostatic charging of a power electrode.

According to aspects of the present disclosure, there are provided a substrate treatment apparatus and a substrate treatment method.

According to an aspect of the present disclosure, there is provided a substrate treatment apparatus including a processing chamber including an upper chamber and a lower chamber having a treatment space for treating a substrate, a substrate support unit provided in the treatment space, the substrate support unit fixing the substrate, a gas supply unit supplying a process gas to the inside of the upper chamber and the treatment space, a plasma generation unit including an upper electrode provided in the upper chamber and a high-frequency power source connected to the upper electrode, the high-frequency power source supplying high-frequency power through an impedance matcher, and a filter unit connected to the upper electrode, the filter unit removing charges accumulated on one surface of the upper electrode.

The filter unit may include a filter circuit connected between the upper electrode and a ground, and the filter circuit may include a low pass filter.

The substrate treatment apparatus may further include a gas feeding unit installed on one surface of the upper electrode, the gas feeding unit receiving the process gas from the gas supply unit and transmitting the process gas to the inside of the processing chamber through the upper electrode. The filter unit may be inserted into the gas feeding unit.

The gas feeding unit may include a feeding block installed on one surface of the upper electrode, a supply pipe provided in the feeding block, the supply pipe having one end formed to communicate with the gas supply unit and the other end formed to communicate with the upper electrode, and a wire inserted into the feeding block, the wire having one end grounded and the other end electrically connected to the upper electrode.

The filter unit may include a filter circuit inserted into the feeding block, the filter circuit connected between the wire and the ground, and the filter circuit may include a low pass filter.

The feeding block may have one surface in which a coupling groove, into which a fastening member is insertable, is formed such that the gas supply unit is coupled thereto.

The wire may have one end connected to the coupling groove so as to be in contact with the fastening member.

The wire may include a contact auxiliary portion provided at one end of the coupling groove, the contact auxiliary portion for contact with the fastening member.

The gas feeding unit may further include a sealing member inserted into at least one of a surface on which the gas supply unit and the supply pipe are in contact with each other or a surface on which the supply pipe and the upper electrode are in contact with each other, so as to prevent leakage of the process gas.

According to another aspect of the present disclosure, there is provided a substrate treatment method performed by a substrate treatment apparatus having a first space disposed between an upper electrode and an ion blocker, a second space disposed between the ion blocker and a shower head, and a treatment space for treating a substrate below the shower head, the substrate treatment method including a mounting operation of mounting a substrate on a substrate support unit provided in the treatment space, a gas supplying operation of supplying, by a first gas supply module, a first process gas to the first space through the upper electrode, a plasma generation operation of supplying, by a plasma generation unit, power to the upper electrode through a high-frequency power source to excite the first process gas into a plasma, a filtering operation of blocking, by a filter unit connected to the upper electrode, a high-frequency power supplied from the high-frequency power source and allowing charges accumulated on one surface of the upper electrode to pass therethrough, and a substrate treatment operation of supplying a plasma effluent to the treatment space, and supplying, by a second gas supply module, a second process gas to the treatment space through the shower head to treat the substrate.

The present disclosure may provide a substrate treatment apparatus and a substrate treatment method for reducing electrostatic charging of a power electrode.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic diagram of a substrate treatment apparatus according to an example embodiment of the present disclosure;

FIG. 2 is a schematic diagram of a filter unit according to an example embodiment of the present disclosure;

FIG. 3 is a schematic diagram of a substrate treatment apparatus according to another example embodiment of the present disclosure;

FIG. 4 is a schematic perspective view of a gas feeding unit according to an example embodiment of the present disclosure;

FIG. 5 is a cross-sectional view taken along line A-A′ of FIG. 4;

FIG. 6 is a cross-sectional view taken along line B-B′ of FIG. 4;

FIG. 7 is a cross-sectional view taken along line C-C′ of FIG. 4; and

FIG. 8 is a flowchart of a substrate treatment method according to an example embodiment of the present disclosure.

### DETAILED DESCRIPTION

Hereinafter, preferred example embodiments will be described in detail, such that the disclosure could be easily carried out. In describing example embodiments of the present disclosure, when it is determined that a detailed description of a known technology related to the present disclosure may unnecessarily obscure the gist of the present disclosure, a detailed description thereof will be omitted. In addition, the same reference numerals are used throughout the drawings with respect to components having similar functions and actions. In addition, in the present specification, terms such as “upper,” “upper portion,” “upper surface,” “lower,” “lower portion,” “lower surface,” and “side surface” are based on the drawings, may vary depending on a direction in which an element or component is actually arranged.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. In addition, it will be understood that “comprises” and/or “comprising” specify the presence of stated features, integers, operations, operations, elements, components or a combination thereof, but do not preclude the presence or addition of one or more other features, integers, operations, operations, elements, components, and/or groups thereof.

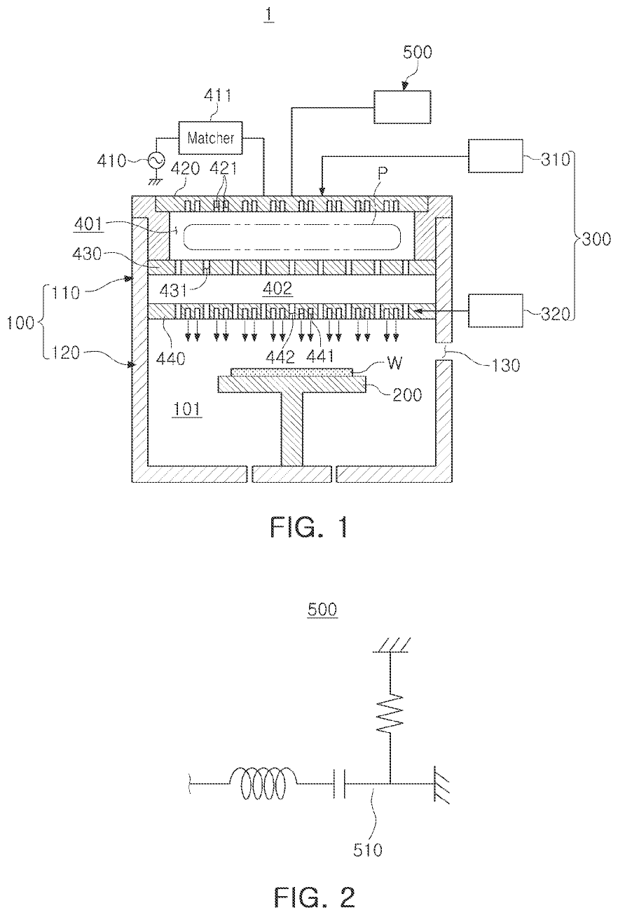

FIG. 1 is a schematic diagram of a substrate treatment apparatus according to an example embodiment of the present disclosure. FIG. 2 is a schematic diagram of a filter unit according to an example embodiment of the present disclosure.

Referring to FIG. 1, a substrate treatment apparatus 1 according to an example embodiment of the present disclosure may include a processing chamber 100, a substrate support unit 200, a gas supply unit 300, and a plasma generation unit 400. The processing chamber 100 may include an upper chamber 110 including an upper electrode 420 and a lower chamber 120 having a treatment space 101 in which a substrate W is treated. In this case, the processing chamber 100 may have a circular cylindrical shape. The processing chamber 100 may be formed of a metal material, for example, an aluminum material. An opening 130 may be formed in one sidewall of the processing chamber 100, and the opening 130 may be used as an entrance through which the substrate W enters and exits. An exhaust port (not illustrated) may be installed on a bottom surface of the processing chamber 100, and the exhaust port (not illustrated) may function as an outlet 150 through which a by-product generated in the treatment space 101 are discharged to the outside of the processing chamber 100. In this case, an exhaust operation may be performed by a pump.

The substrate support unit 200 may be installed in the treatment space 101 and may support the substrate W. The substrate support unit 200 may be an electrostatic chuck supporting the substrate W using electrostatic force. The electrostatic chuck may include a dielectric plate disposed on an upper surface of the substrate W, an electrode installed in the dielectric plate, the electrode supplying electrostatic force to adsorb the substrate W, and a heater installed in the dielectric plate, the heater heating the substrate W.

The gas supply unit 300 may supply a process gas to the inside of the processing chamber 100, and the gas supply unit 300 may include a first gas supply module 310 and a second gas supply module 320. The first gas supply module 310 may supply a first process gas to the upper chamber 110, and the first process gas may be a fluorine-containing gas, for example, nitrogen trifluoride (NF₂) gas. The second gas supply module 320 may supply a second process gas to the inside of the treatment space 101, and the second process gas may be a nitrogen-and hydrogen-containing gas, for example, ammonia (NH₂) gas. As a result, nitrogen trifluoride (NF₂) may be excited in the form of a plasma within the upper chamber 110, and a plasma effluent and ammonia (NH₂) may react to form an etchant for etching the substrate W. The first gas supply module 310 may further supply a third process gas, and the third process gas may be an inert gas, for example, Ar or Ne. The third process gas may be supplied together with the first process gas, and may assist the movement of the first process gas.

The plasma generation unit 400 may include a high-frequency power source 410, an upper electrode 420, an ion blocker 430, and a shower head 440, and may serve as a capacitively coupled plasma source. The upper electrode 420 may be provided in the upper chamber 11, and the high-frequency power source 410 may be connected to the upper electrode 420 and may supply high-frequency power through an impedance matcher 411. The shower head 440 may divide the processing chamber 100 into the upper chamber 110 and the lower chamber 120, and the ion blocker 430 may be provided in the upper chamber 110, and may be provided between the upper electrode 420 and the shower head 440. In this case, a first space 401 may be disposed between the upper electrode 420 and the ion blocker 430, a second space 402 may be disposed between the ion blocker 430 and the shower head 440, and a treatment space 101 may be positioned below the shower head 440. That is, the upper chamber 110 may provide the first space 401 and the second space 402, and the lower chamber 120 may provide the treatment space 101.

In the substrate treatment apparatus 1 according to an example embodiment of the present disclosure, the first gas supply module 310 may be connected to the upper electrode 420, and the first process gas and/or the third process gas may be supplied to the first space 401. More specifically, the first process gas supplied through the first gas supply module 310 may be supplied to the first space 401 through a first gas supply hole 421 formed in the upper electrode 420. In addition, the substrate treatment apparatus 1 according to an example embodiment of the present disclosure may supply the high-frequency power source 410 to the upper electrode 420 to excite the first process gas supplied to the first space 401 in the form of a plasma. The first process gas excited in the form of a plasma may include radicals, ions and/or electrons.

The plasma formed in the first space 401 may be filtered while passing through the ion blocker 430. That is, the ion blocker 430 may be connected to a constant voltage, and radicals or uncharged neutral species, among effluents of the plasma, may be supplied to the second space 402 through a first through-hole 431 formed in the ion blocker 430 in a vertical direction. Conversely charged species (that is, ions) may be filtered without passing through the first through-hole 431. As a result, the filtered plasma effluent may pass through the ion blocker 430 through the first through-hole 431 and may be supplied to the second space 402.

In this case, the shower head 440 may be connected to the second gas supply module 320, and the plasma effluent, supplied to the second space 402, may pass through the shower head 440 and may be supplied to the treatment space 101. That is, the shower head 440 may further include a second gas supply hole 441 formed to receive the second process gas from the second gas supply module 320 and to supply the second process gas to the treatment space 101, and a second through-hole 442 formed to communicate with the second space 402 so as to supply the plasma supplied to the second space 402 to the treatment space 101. Accordingly, the plasma effluent, supplied to the second space 402, may be supplied to the treatment space 101 through the second through-hole 442, and the plasma effluent may react and mix with the second process gas supplied through the second gas supply hole 441, and may form, for example, an etchant for etching silicon oxide.

In this case, the upper electrode 420 may be charged with static electricity by power supply from the high-frequency power source 410, and a phenomenon in which charges are accumulated may occur as coolant (not illustrated) circulates in the upper electrode 420. The charges accumulated in the upper electrode 420 may generate micro arcing during a plasma generation process.

In order to solve the above-described issue, the substrate treatment apparatus 1 according to an example embodiment of the present disclosure may further include a filter unit 500. The filter unit 500 may be connected to the upper electrode 420, and may remove charges accumulated on one surface of the upper electrode 420 in response to power supply from the high-frequency power source 410.

For example, the filter unit 500 according to an example embodiment of the present disclosure may include a discharge control circuit (not illustrated), and the discharge control circuit (not illustrated), a passive or active circuit, may move charges, causing the charges to be consumed in a resistor (not illustrated). As a result, the filter unit 500 may remove the charges accumulated on the one surface of the upper electrode 420. In another example embodiment, the filter unit 500 may detect a type of charge charged on the one surface of the upper electrode 420 through a charge detector (not illustrated), and may generate positive or negative ions through an ion generation unit (not illustrated) and transfer the positive or negative ions to the one surface of the upper electrode 420 to remove the charged charges. The filter unit 500 may be applied without limitation as long as the filter unit 500 is capable of removing the charges accumulated on the one surface of the upper electrode 420.

More specifically, the filter unit 500 according to an example embodiment of the present disclosure may include a filter circuit 510 connected between the upper electrode 420 and a ground, and the filter circuit 510 may include a low pass filter. Referring to FIG. 2, one end of the filter circuit 510 may be grounded and the other end of the filter circuit 510 may be connected to one surface of the upper electrode 420, such that the charges accumulated on the one surface of the upper electrode 420 may be moved to the ground and removed. At the same time, high-frequency power generated from the high-frequency power source 410 may not pass through the filter circuit 510, such that loss of high-frequency power to the ground may be prevented. As a result, the substrate treatment apparatus 1 according to an example embodiment of the present disclosure may prevent charges from accumulating on the upper electrode 420 even during plasma generation and simultaneously may prevent high-frequency power from being short-circuited.

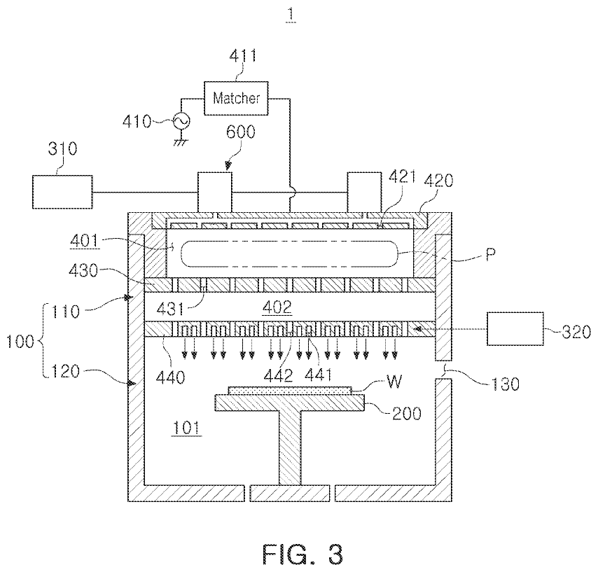

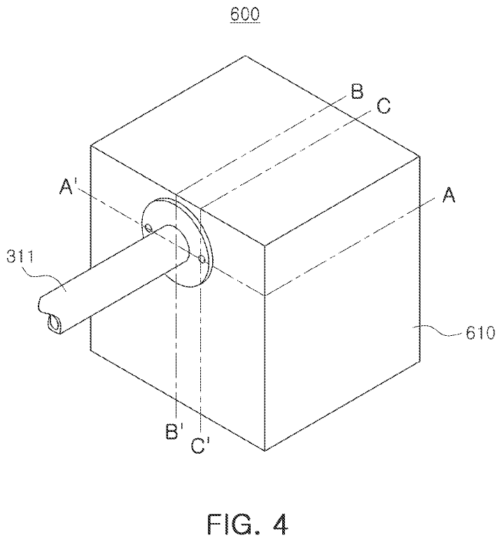

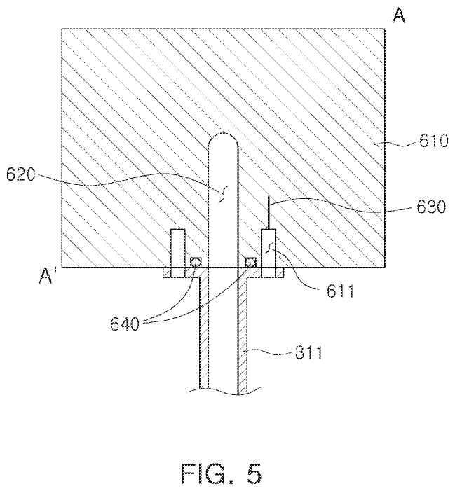

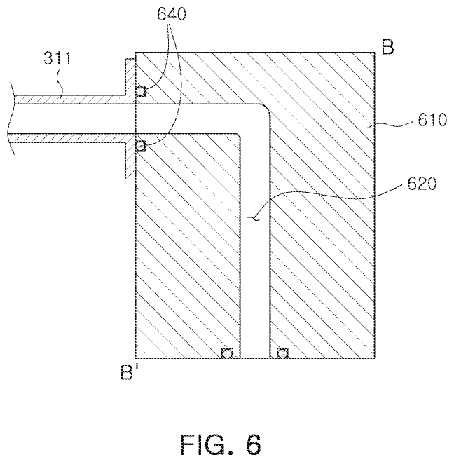

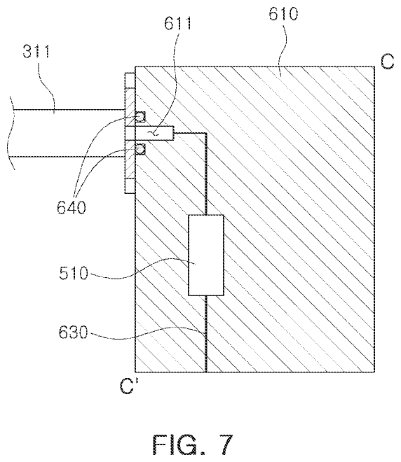

FIG. 3 illustrates a substrate treatment apparatus 1 according to another example embodiment of the present disclosure, and FIGS. 4 to 7 illustrate a gas feeding unit 600 included in the substrate treatment apparatus 1 according to another example embodiment of the present disclosure. More specifically, FIG. 4 is a schematic perspective view of a gas feeding unit 600 according to an example embodiment of the present disclosure, FIG. 5 is a cross-sectional view taken along line A-A′ of FIG. 4, FIG. 6 is a cross-sectional view taken along line B-B′ of FIG. 4, and FIG. 7 is a cross-sectional view taken along line C-C′ of FIG. 4. Hereinafter, with reference to FIGS. 3 to 7, the substrate treatment apparatus 1 according to another example embodiment of the present disclosure will be described, and descriptions overlapping the above-descriptions of the substrate treatment apparatus 1 according to an example embodiment of the present disclosure will be described. Differences between the substrate treatment apparatus 1 according to an example embodiment and the substrate treatment apparatus 1 according to another example embodiment will be mainly described.

The substrate treatment apparatus 1 according to another example embodiment of the present disclosure may further include a gas feeding unit 600. The gas feeding unit 600 may be connected to an upper electrode 420 and may receive a process gas from the gas supply unit 300 and transmit the process gas to the inside of the processing chamber 100. In this case, a filter unit 500 may be inserted into the gas feeding unit 600. The gas feeding unit 600 may be installed on one surface of the upper electrode 420.

The gas feeding unit 600 may include a feeding block 610, a supply pipe 620, and a wire 630. The feeding block 610 may be installed on the one surface of the upper electrode 420, may have a quadrangular columnar shape, and may be formed of a resin-based material. The supply pipe 620 may be provided in the feeding block 610, and one end of the supply pipe 620 may be formed to communicate with the gas supply unit 300, and the other end of the supply pipe 620 may be formed to communicate with the upper electrode 420. As a result, the process gas supplied from the gas supply unit 300 may be supplied to a first space 401 through the upper electrode 420. The wire 630 may be formed of a conductive material, may be inserted into the feeding block 610, and may have one end grounded and the other end electrically connected to the upper electrode 420. In this case, the filter unit 500 may be inserted into the feeding block 610, and may further include a filter circuit 510 connected between the wire 630 and the ground, and the filter circuit 510 may include a low pass filter. As a result, charges accumulated in the upper electrode 420 may be moved to the ground along the wire 630 and removed. Conversely, high-frequency power may be blocked by the filter circuit 510. Thus, the substrate treatment apparatus 1 may remove the charges of the upper electrode and simultaneously may prevent loss caused by grounding of high-frequency power.

The gas feeding unit 600 may be connected to a first gas supply module 310, and may receive a first process gas from the first gas supply module 310 and supply the first process gas to the first space 401 through the upper electrode 420. That is, one end of the supply pipe 620 may be connected to be in communication with a first supply line 311 of the first gas supply module 310, and the other end of the supply pipe 620 may be connected to be in communication with the upper electrode 420. In this case, the supply pipe 620 may have an “L” shape. Accordingly, the first process gas may be supplied from the first gas supply module 310 to the upper electrode 420 through the gas feeding unit 600. In this case, the first supply line 311 may be coupled to the feeding block 610 as a fastening member (not illustrated) passes through the feeding block 610, and the feeding block 610 may have one surface in which a coupling groove 611, into which the fastening member (not illustrated) is insertable, is formed such that the first supply line 311 is coupled thereto. As a result, as the fastening member (not illustrated) passes through the feeding block 610 and is inserted into the coupling groove 611, the first gas supply module 310 may be coupled to the feeding block 610.

In addition, the gas feeding unit 600 may further include a sealing member 640 inserted into at least one of a surface on which the first supply line 311 and the supply pipe 620 are in contact with each other or a surface on which the supply pipe 620 and the upper electrode 420 are in contact with each other, so as to prevent leakage of the process gas. The sealing member 640 may be provided to surround the outside of the supply pipe 620, and may be positioned inside the coupling groove 611. To this end, the feeding block 610 may have a groove around one end of the supply pipe 620 such that the sealing member 640 is inserted thereinto, and the sealing member 640 may be inserted into the groove, thereby preventing the first process gas from leaking during transport.

The wire 630 may be connected to the coupling groove 611 such that one end of the wire 630 is in contact with the fastening member (not illustrated). Accordingly, the one end of the wire 630 may be grounded by contact with the fastening member (not illustrated), and the other end of the wire 630 may be electrically connected to the upper electrode 420, thereby removing the charges accumulated on the one surface of the upper electrode 420. In addition, the wire 630 may further include a contact auxiliary portion (not illustrated) provided at one end of the coupling groove 611, the contact auxiliary portion for contact with the fastening member (not illustrated). For example, although not illustrated in the drawings, the contact auxiliary portion (not illustrated) may refer to a portion in which the one end of the wire 630 has a spring shape, or may refer to a cushion (not illustrated) for a contact point between the fastening member (not illustrated) and the one end of the wire 630. However, any configuration facilitating the contact point between the wire 630 and the fastening member (not illustrated) may be applied without being limited thereto. Accordingly, the substrate treatment apparatus 1 according to another example embodiment of the present disclosure may facilitate the wire 630 being grounded.

According to the above-described structure, the substrate treatment apparatus 1 according to another example embodiment of the present disclosure may insert a low pass filter LPF into the gas feeding unit 600, such that the charges accumulated in the upper electrode 420 may be moved to the ground along the wire 630, and the low pass filter LPF may serve as an RF choke capable of preventing high-frequency power supplied from the high-frequency power source 410 from being grounded. In addition, in the substrate treatment apparatus 1, the filter circuit 510 may be inserted into the gas feeding unit 600 to be integrated with the gas feeding unit 600, without installation or replacement of the filter unit 500, thereby continuously preventing charges from being accumulated and not requiring installation or replacement of the filter circuit 510.

The substrate treatment apparatus 1 according to an example embodiment of the present disclosure has been described as having a structure using a capacitively coupled plasma (CCP) source including a double chamber, but the present disclosure is not limited thereto. A structure using an inductively coupled plasma (ICP) source may be applicable as long as the filter unit 500 is capable of removing charges accumulated on one surface of an electrode supplying power.

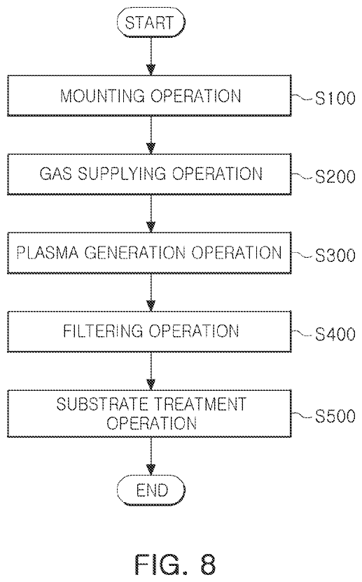

FIG. 8 is a flowchart of a substrate treatment method according to an example embodiment of the present disclosure.

A substrate treatment method according to an example embodiment of the present disclosure may include a mounting operation (S100), a gas supplying operation (S200), a plasma generation operation (S300), a filtering operation (S400), and a substrate treatment operation (S500). A configuration of the substrate treatment apparatus 1 described with reference to FIGS. 1 to 3 may be applied to the substrate treatment method. For example, as illustrated in FIG. 3, the substrate treatment method may be described by the substrate treatment apparatus having the first space 401 disposed between the upper electrode 420 and the ion blocker 430, a second space 402 disposed between the ion blocker 430 and the shower head 440, and the treatment space 101 for treating the substrate W below the shower head 440. Hereinafter, the substrate treatment method according to an example embodiment of the present disclosure will be described in detail with reference to FIGS. 1, 3, and 8.

First, in the seating operation (S100), a substrate W may be mounted on a substrate support unit 200 provided in the treatment space 101. In the gas supplying operation (S200), a first gas supply module 310 may supply a first process gas to the first space 401 through an upper electrode 420. Here, the first process gas may be a fluorine-containing gas, for example, nitrogen trifluoride (NF₂) gas. More specifically, the gas supplying operation (S200) may include an operation of transmitting, by the first gas supply module 310, the first process gas to a gas feeding unit 600 provided on one surface of the upper electrode 420, and an operation of supplying, the gas feeding unit 600, the first process gas to the first space 401 through a first gas supply hole 421 formed in the upper electrode 420. That is, the first gas supply module 310 may supply the first process gas to the first space 401 through the gas feeding unit 600.

In the plasma generation operation (S300), the plasma generation unit 400 may supply power to the upper electrode 420 through a high-frequency power source 410 to excite the first process gas into a plasma. For example, nitrogen trifluoride (NF₂) the first process gas, may be excited in the form of a plasma within the first space 401. In the plasma generation operation (S300), charges may be accumulated on one surface of the upper electrode 420, and an arcing phenomenon may occur during plasma generation due to the accumulated charges.

In the filtering operation (S400), a filter unit 500, connected to the upper electrode 420, may block high-frequency power supplied from the high-frequency power source 410, and may allow charges accumulated on one surface of the upper electrode 420 to pass therethrough. In this case, the filtering operation (S400) may be performed simultaneously with the plasma generation operation (S300). When a filter circuit 510 to be described below is connected, the filtering operation may be continuously performed before the plasma generation operation (S300) is started. As a result, in the substrate treatment method according to an example embodiment of the present disclosure, micro arcing may be prevented by preventing charges from being accumulated on a surface of the upper electrode 420, and the plasma generation operation (S300) may be continuously performed without high-frequency power being short-circuited.

In this case, the filter unit 500 may be provided in the gas feeding unit 600, and may include a filter circuit 510 connected between the upper electrode 420 and a ground. The filter circuit 510 may include a low pass filter. Accordingly, the substrate treatment method according to an example embodiment of the present disclosure may remove the charges accumulated on the one surface of the upper electrode 420 using the filter circuit 510 and simultaneously may block high-frequency power to prevent loss caused by grounding of high-frequency power.

In the substrate treatment operation (S500), an effluent of a plasma generated in the first space 401 may be supplied to the treatment space 101, and a second gas supply module 320 may supply a second process gas to the treatment space 101 through the shower head 440 to treat the substrate W. Here, the second process gas may be a nitrogen- and hydrogen-containing gas, for example, ammonia (NH₂) gas. The plasma effluent and ammonia (NH₂) may react to form an etchant for etching the substrate W.

Accordingly, in the substrate treatment method according to an example embodiment of the present disclosure, charges accumulated on one surface of an upper electrode may be removed by performing the filtering operation (S400), thereby preventing arcing, and high-frequency power may be blocked by a filter circuit, thereby performing the plasma generation operation (S300) without high-frequency power being short-circuited.

While example embodiments have been shown and described above, it will be apparent to those skilled in the art that modifications and variations could be made without departing from the scope of the present disclosure as defined by the appended claims.

What is claimed is:

1. A substrate treatment apparatus comprising:
a processing chamber including an upper chamber and a lower chamber having a treatment space for treating a substrate;
a substrate support unit provided in the treatment space, the substrate support unit fixing the substrate;
a gas supply unit supplying a process gas to the inside of the upper chamber and the treatment space;
a plasma generation unit including an upper electrode provided in the upper chamber and a high-frequency power source connected to the upper electrode, the high-frequency power source supplying high-frequency power through an impedance matcher; and
a filter unit connected to the upper electrode, the filter unit removing charges accumulated on one surface of the upper electrode.

2. The substrate treatment apparatus of claim 1, wherein
the filter unit includes a filter circuit connected between the upper electrode and a ground, and
the filter circuit includes a low pass filter.

3. The substrate treatment apparatus of claim 1, further comprising:
a gas feeding unit installed on one surface of the upper electrode, the gas feeding unit receiving the process gas from the gas supply unit and transmitting the process gas to the inside of the processing chamber through the upper electrode,
wherein the filter unit is inserted into the gas feeding unit.

4. The substrate treatment apparatus of claim 3, wherein the gas feeding unit includes:
a feeding block installed on one surface of the upper electrode;
a supply pipe provided in the feeding block, the supply pipe having one end formed to communicate with the gas supply unit and the other end formed to communicate with the upper electrode; and
a wire inserted into the feeding block, the wire having one end grounded and the other end electrically connected to the upper electrode.

5. The substrate treatment apparatus of claim 4, wherein
the filter unit includes a filter circuit inserted into the feeding block, the filter circuit connected between the wire and the ground, and
the filter circuit includes a low pass filter.

6. The substrate treatment apparatus of claim 5, wherein the feeding block has one surface in which a coupling groove, into which a fastening member is insertable, is formed such that the gas supply unit is coupled thereto.

7. The substrate treatment apparatus of claim 6, wherein the wire has one end connected to the coupling groove so as to be in contact with the fastening member.

8. The substrate treatment apparatus of claim 7, wherein the wire includes a contact auxiliary portion provided at one end of the coupling groove, the contact auxiliary portion for contact with the fastening member.

9. The substrate treatment apparatus of claim 8, wherein the gas feeding unit further includes:
a sealing member inserted into at least one of a surface on which the gas supply unit and the supply pipe are in contact with each other or a surface on which the supply pipe and the upper electrode are in contact with each other, so as to prevent leakage of the process gas.

10. The substrate treatment apparatus of claim 9, wherein
the plasma generation unit further includes:
a shower head dividing the treatment chamber into the upper chamber and the lower chamber; and
an ion blocker provided in the upper chamber, the ion blocker provided between the upper electrode and the shower head, and
a first space is disposed between the upper electrode and the ion blocker, a second space is disposed between the ion blocker and the shower head, and a treatment space is positioned below the shower head.

11. The substrate treatment apparatus of claim 10, wherein the gas supply unit includes:
a first gas supply module connected to the gas feeding unit, the first gas supply module supplying a first process gas to the first space; and
a second gas supply module connected to the shower head, the second gas supply module supplying a second process gas to the treatment space.

12. The substrate treatment apparatus of claim 11, wherein
the upper electrode has a first gas supply hole to communicate with the supply pipe of the feeding block, and
the first process gas is supplied to the first space through the supply pipe and the first gas supply hole.

13. The substrate treatment apparatus of claim 12, wherein the shower head further includes:
a second gas supply hole formed to receive the second process gas from the second gas supply module and to supply the second process gas to the treatment space; and
a second through-hole formed to communicate with the second space so as to supply a plasma effluent provided in the second space to the treatment space.

14. The substrate treatment apparatus of claim 13, wherein the ion blocker is connected to a constant voltage, filters a plasma formed in the first space, and has a first through-hole to supply a plasma effluent to the second space.

15. The substrate treatment apparatus of claim 14, wherein the first process gas is a fluorine-containing gas, and the second process gas is a nitrogen-and hydrogen-containing gas.

16. The substrate treatment apparatus of claim 15, wherein
the first gas supply module further supplies a third process gas through the gas feeding unit and the upper electrode, and
the third process gas is an inert gas.

17. A substrate treatment method performed by a substrate treatment apparatus having a first space disposed between an upper electrode and an ion blocker, a second space disposed between the ion blocker and a shower head, and a treatment space for treating a substrate below the shower head, the substrate treatment method comprising:
a mounting operation of mounting a substrate on a substrate support unit provided in the treatment space;
a gas supplying operation of supplying, by a first gas supply module, a first process gas to the first space through the upper electrode;
a plasma generation operation of supplying, by a plasma generation unit, power to the upper electrode through a high-frequency power source to excite the first process gas into a plasma;
a filtering operation of blocking, by a filter unit connected to the upper electrode, a high-frequency power supplied from the high-frequency power source and allowing charges accumulated on one surface of the upper electrode to pass therethrough; and
a substrate treatment operation of supplying a plasma effluent to the treatment space, and supplying, by a second gas supply module, a second process gas to the treatment space through the shower head to treat the substrate.

18. The substrate treatment method of claim 17, wherein the gas supplying operation includes:
an operation of transmitting, by the first gas supply module, a first process gas to a gas feeding unit provided on the one surface of the upper electrode; and
an operation of supplying, by the gas feeding unit, the first process gas to the first space through a first gas supply hole formed in the upper electrode.

19. The substrate treatment method of claim 18, wherein
the filter unit is a filter circuit provided in the gas feeding unit, the filter circuit connected between the upper electrode and a ground, and
the filter circuit includes a low pass filter.

20. A substrate treatment apparatus comprising:
a processing chamber having a first space disposed between an upper electrode and an ion blocker, a second space disposed between the ion blocker and a shower head, and a treatment space for treating a substrate below the shower head;
a substrate support unit provided in the treatment space, the substrate support unit in which an electrostatic chuck, fixing the substrate, is installed;
a gas supply unit including a first gas supply module supplying a first process gas to the first space and a second gas supply module supplying a second process gas to the treatment space;
a plasma generation unit connected to the upper electrode, the plasma generation unit having a high-frequency power source supplying high-frequency power through an impedance matcher;
a gas feeding unit installed on one surface of the upper electrode, the gas feeding unit connected to the first gas supply module, the gas feeding unit receiving the first process gas from the first gas supply module and transmitting the first process gas to the inside of the first space; and
a filter unit provided in the gas feeding unit, the filter unit blocking high-frequency power supplied from the plasma generation unit and allowing charges accumulated on one surface of the upper electrode to pass therethrough,
wherein the gas feeding unit includes:
a feeding block provided to be in contact with an upper surface of the upper electrode;
a supply pipe provided in the feeding block, the supply pipe having one end formed to communicate with the gas supply unit and the other end formed to communicate with the upper electrode; and
a wire inserted into the feeding block, the wire having one end grounded and the other end electrically connected to the upper electrode,
the filter unit includes a filter circuit electrically connected to the wire, and
the filter circuit includes a low pass filter.
